(19) United States
(12) Patent Application Publication
(10) Pub. No.: US 2007/0181921 A1
(43) Pub. Date: Aug. 9, 2007

(54) Display device and manufacturing method therefor

(76) Inventors: Sung-jin Kim, Gyeonggi-do (KR); Son-uk Lee, Gyeonggi-do (KR)

Correspondence Address: MACPHERSON KWOK CHEN & HEID LLP, 2033 GATEWAY PLACE, SUITE 400, SAN JOSE, CA, 95110, US

(21) Appl. No.: 11/653,659

(22) Filed: Jan. 12, 2007

(30) Foreign Application Priority Data
Jan. 16, 2006 (KR) 2006-0004547

(51) Int. Cl. H01L 31/113

(52) U.S. Cl. 257/290

(57) ABSTRACT

A display device includes a first insulating substrate having thin film transistors; a second insulating substrate of plastic having a black matrix comprising a plurality of horizontal extending portions extending in one directions and a plurality of vertical portions extending at an irregular interval in a second direction perpendicular to the first direction; and a liquid crystal layer located between the first substrate and the second substrate.

### CROSS-REFERENCE TO RELATED APPLICATIONS

This application claims the benefit of Korean Patent Application No. 2006-0004547, filed on Jan. 16, 2006, in the Korean Intellectual Property Office, the disclosure of which is incorporated herein by reference.

### FIELD OF THE INVENTION

The present invention relates to a display device having black matrixes formed on a plastic insulating substrate better aligned with color filters.

### DESCRIPTION OF THE RELATED ART

An LCD flat panel display includes an LCD panel having a thin film transistor (TFT) substrate, a color filter substrate opposite the TFT substrate and a liquid crystal layer located between the two substrates. A backlight unit is located in back of the TFT substrate to provide light to the LCD panel. For lightness and thinness a plastic insulating substrate may be used. Under certain circumstances, however, misalignment of the color filters with the black matrixes may occur.

### SUMMARY OF THE INVENTION

In accordance with an aspect of the present invention improved alignment of black matrixes with color filters is provided in a display device having a first insulating substrate comprising a first insulating substrate and thin film transistors formed on the first insulating substrate; a second substrate facing the first substrate and comprising a second insulating substrate made of plastic and a black matrix formed on the second insulating substrate, the black matrix comprising a plurality of horizontal extending portions extending in a first direction and disposed at fixed or irregular intervals and a plurality of vertical extending portions extending in a second, perpendicular direction and disposed at an irregular interval; and a liquid crystal layer located between the first and second substrates. According to an embodiment of the present invention, the vertical extending portions comprise: a first sub vertical portion having a first vertical width and a second sub vertical portion having a second vertical width larger than the first vertical width.

According to an embodiment of the present invention, the second substrate further comprises color filters formed on the black matrixes with a constant interval.

According to the embodiment of the present invention, an interval between the adjacent horizontal extending portions includes first horizontal intervals and second horizontal intervals smaller than the first horizontal intervals, and wherein the horizontal extending portions comprise: a first sub horizontal portion having a first horizontal width; and a second sub horizontal portion having a second horizontal width larger than the first horizontal width.

According to the embodiment of the present invention, the display device further comprises color filters formed on the black matrixes and the second insulating substrate, the color filters having a plurality of sub layers extending in the second direction and having an irregular interval.

The display device of the invention may be manufactured by: forming a black matrix on an insulating plastic substrate, the black matrix comprising a plurality of horizontal extending portions extending in a first direction and a plurality of vertical extending portions having an irregular interval and extending in a second direction perpendicular to the first direction; and forming color filters in openings formed in the black matrix with a constant interval.

### BRIEF DESCRIPTION OF THE DRAWINGS

The above and/or other aspects and advantages of the present invention will become apparent from the following description of the embodiments, taken in conjunction with the accompanying drawings, in which:

FIG. 1 is a perspective view of a display device according to a first embodiment of the present invention;

FIG. 2 is a sectional view taken along line II-II of FIG. 1;

FIG. 3 is a sectional view taken along line III-III of FIG. 1;

FIG. 4 is a view illustrating black matrixes in the display device according to the first embodiment of the present invention;

FIG. 5 is a view illustrating color filters in the display device according to the first embodiment of the present invention;

FIG. 6 is a sectional view illustrating alignment of black matrixes with color filters in the display device according to the first embodiment of the present invention;

FIG. 7 is a sectional view to explain a manufacturing method of the display device according to the first embodiment of the present invention;

FIG. 8 is a sectional view illustrating alignment of black matrixes with color filters in a display device according to a second embodiment of the present invention;

FIG. 9 is a view illustrating black matrixes in a display device according to a third embodiment of the present invention;

FIG. 10 is a view illustrating color filters in the display device according to the third embodiment of the present invention; and

FIG. 11 is a sectional view illustrating alignment of black matrixes with color filters in a display device according to a fourth embodiment of the present invention.

### DETAILED DESCRIPTION OF THE PREFERRED EMBODIMENT

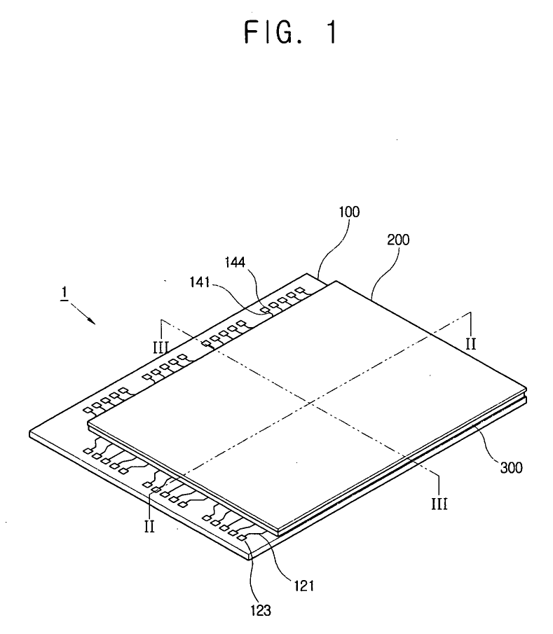

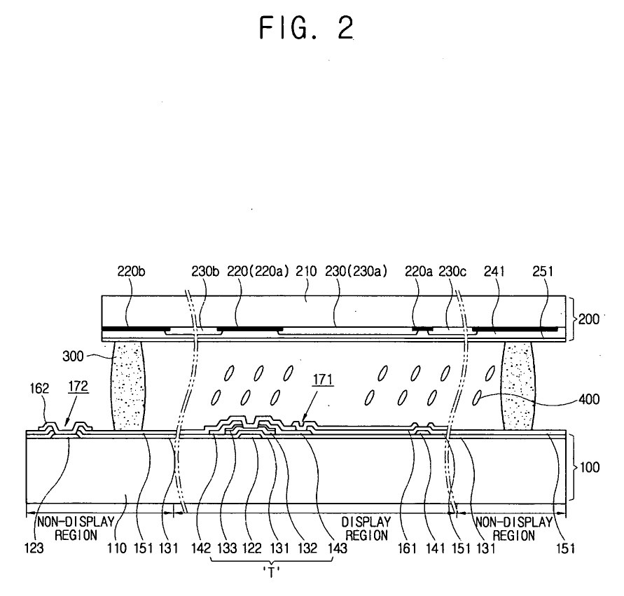

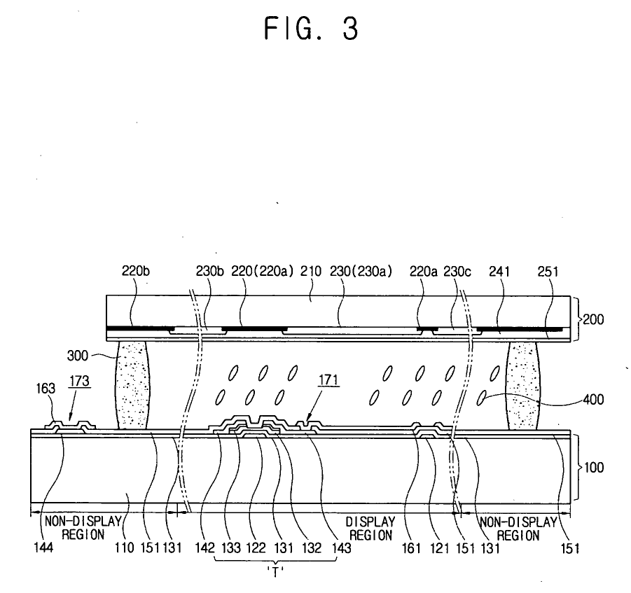

A display device according to a first embodiment of the present invention will be described with reference to FIGS. 1 to 3. A display device 1 includes a first substrate 100 on which TFTs T are formed, a second substrate 200 opposite to the first substrate 100 and on which a common electrode 251 is formed, a sealant 300 adhering both substrates 100 and 200 together, and a liquid crystal layer 400 bounded by substrates 100, 200 and sealant 300. First and second substrates 100 and 200 are rectangular in shape, with the first substrate 100 somewhat larger than the second substrate 200. The first and second substrates 100 and 200 are each divided into a display region in which the TFTs T are located and a non-display region surrounding the display region and at which the sealant 300 and pads 123 and 144 are formed.

The first substrate 100 will be now described in detail. Gate conductor lines 121, 122 and 123 are formed on a first insulating substrate 110, which may be made of plastics or glass.

Gate conductor lines 121, 122 and 123 include gate lines 121 extending in parallel transversely, gate electrodes 122 of the TFTs T which are connected to the gate lines 121, and gate pads 123 provided at the ends of the gate lines 121. Gate pads 123 are wider than gate lines 121 in order to facilitate their connection to an external circuit.

A gate insulating film 131 made of silicon nitride (SiNx) is formed on the first insulating substrate 110 and on gate conductor lines 121, 122 and 123.

A semiconductor layer 132 made of a semiconductor material such as amorphous silicon or the like is formed on gate insulating film 131 of gate electrode 122, and an ohmic contact layer 133 made of a material such as silicide, n+ hydrogenated amorphous silicon heavily doped with n-type impurities, or the like is formed on semiconductor layer 132. Semiconductor layer 132 has an island-like shape on gate electrode 122 and ohmic contact layer 133 is divided into two portions around gate electrode 122.

Data conductor lines 141, 142, 143 and 144 are formed on ohmic contact layer 133 and gate insulating film 131. Data conductor lines 141, 142, 143 and 144 include a data line 141 formed perpendicular to gate line 121, with pixels defined by the intersection of data line 141 and gate line 121. A source electrode 142, which is a branch of data line 141, extends to the top of ohmic contact layer 133, a drain electrode 143 is formed opposite to and separated from source electrode 142 around gate electrode 122, and data pads 144 are formed at the end of data line 141. Data pads 144 are wider than data line 141 i to facilitate their connection to an external circuit.

A passivation film 151 made of a material such as silicon nitride, a-Si:C:O or a-Si:O:F deposited by a plasma enhanced chemical vapor deposition (PECVD) method is formed on the data conductor lines 141, 142, 143 and 144 and a portion of the semiconductor layer 132, which is not covered with the data conductor lines 141, 142, 143 and 144. In the passivation film 151 are formed a contact hole 171 exposing the drain electrode 143, a contact hole 172 exposing the gate pad 123, and a contact hole 173 exposing the data pad 144.

Transparent conductive layers 161, 162 and 163 made of a transparent conductive material such as indium tine oxide (ITO) or indium zinc oxide (IZO) are formed on the passivation film 151. The transparent conductive layers 161, 162 and 163 includes a pixel electrode 161 connected to the TFT T via contact hole 171 exposing drain electrode 143, a first contact member 162 formed on the contact hole 172 exposing gate pad 123, and a second contact member 163 formed on contact hole 173 exposing data pad 144.

Next, the second substrate 200 opposite to the first substrate 100 will be described in detail. Black matrixes 220 are formed on a second insulating substrate 120, which may be made of plastic such as polycarbonate, polyimide, polyethersulfone (PES), polyarylate (PAR), polyethylenenaphtalate (PEN), polyethyleneterephthalate (PET) or the like.

Black matrixes 220, in the form of a lattice, include inner black matrixes 220a formed in the display region and outer black matrixes 220b formed in the non-display region. The inner black matrixes 220a are formed to correspond to gate line 121, data line 141 and TFT T. The inner black matrixes 220a block external light from the channel region of the TFT T, and outer black matrixes 220b are formed to surround the display region. Outer black matrixes 220b are wider than inner black matrixes 220a. Black matrixes 220 (including the inner and outer black matrixes 220a and 220b) may be made of chrome oxide, or organic materials containing black pigments.

Color filters 230 are formed between the black matrixes 220. The color filters 230 are regularly formed. That is, three sub layers 230a, 230b and 230c having different colors are repeatedly formed.

An overcoat layer 241 is formed on color filters 230 to planarize the surface.

A common electrode 251 is formed on overcoat layer 241. Common electrode 251, which is made of a transparent conductive material such as ITO, IZO or the like, controls alignment of molecules in the liquid crystal layer 400 by applying a voltage to the liquid crystal layer 400 in combination with the pixel electrode 161.

Although not shown, alignment films are formed on pixel electrode 161 and common electrode 251, respectively. The alignment films are typically made of polyimide and are rubbed to orient the molecules in the liquid crystal layer 400 in a specific direction.

Sealant 300 is applied in the non-display region along the circumference of the display region and contains ultraviolet curing resin such as acryl resin or may further contain a thermosetting resin such as epoxy resin, amine curing agent, a filler such as alumina powder, and a spacer.

The liquid crystal layer 400 is located in the space between substrates 100 and 200, and alignment of the molecules therein is changed by a voltage difference between the pixel electrode 161 and the common electrode 251.

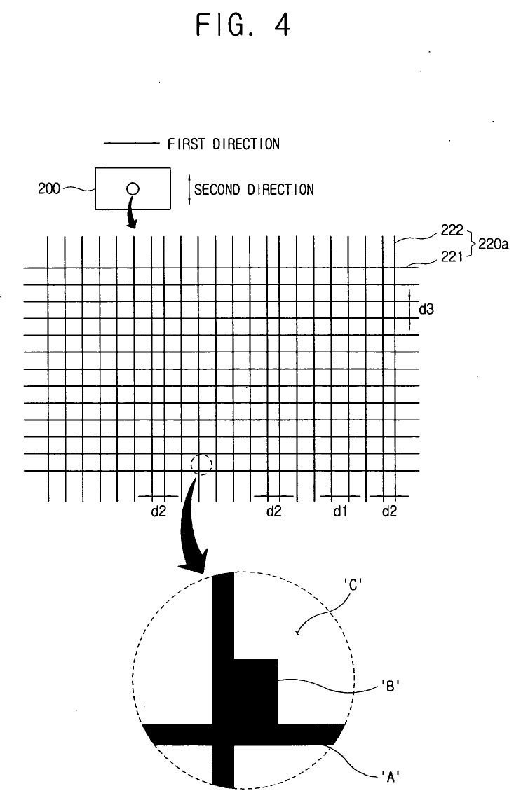

Hereinafter, the black matrixes 220 of the display device according to the first embodiment of the present invention will be described in more detail with reference to FIG. 4. FIG. 4 shows a portion of an inner black matrix in the display region.

Inner black matrix 220a includes a horizontal extending portion 221 and a vertical extending portion 222. The horizontal extending portion 221 and the vertical extending portion 222 are perpendicular to each other, defining an opening C.

A narrow line segment A of the inner black matrix 220a overlaps gate line 121 and data line 141, and a wide line segment B at an intersection portion of the horizontal extending portion 221 and the vertical extending portion 222 overlaps the TFT.

The second substrate 200 including the inner black matrix 220a has a largely rectangular shape. The horizontal extending portion 221 extends in a first direction in parallel to the long sides of the second substrate 200, while the vertical extending portion 222 extends in a second direction in parallel to the shorts sides of the second substrate 200.

Intervals between inner black matrixes 220a will be now considered below.

The spacing between vertical extending portions 222 is irregular and includes a first interval d1 and a second interval d2 narrower than the first interval d2. The first interval d1 and the second interval d2 have a regular pattern of one second interval d2 every six first intervals d1.

The second interval d2 may be 70% to 98% of the first interval d1. If the second interval d2 is less than 70% of the first interval d1, an area of the opening C is excessively reduced. If the second interval d2 is more than 98% of the first interval d1, an alignment between the color filters 230 and black matrixes 220 deteriorates. A size of the second interval d2 depends on a thermal expansion coefficient of the second insulating substrate 210, temperature conditions for manufacture of the color filters 230, a ratio of the first interval d1 to the second interval d2, etc. The interval between horizontal extending portions 221 is a regular third interval d3.

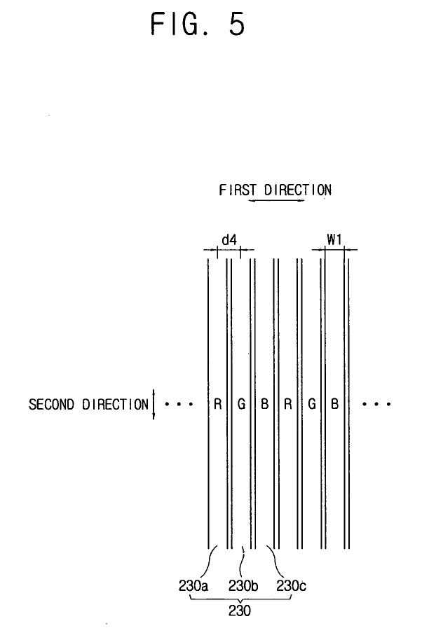

FIG. 5 is a view illustrating color filters in the display device according to the first embodiment of the present invention.

Color filters 230 extend along the second direction in parallel to the short sides of the second substrate 200, with the sub layers 230a, 230b and 230c repeatedly formed. The color filters 230 are arranged at regular intervals, with an interval between the sub layers 230a, 230b and 230c as a fourth interval d4. The width of each color filter 230 is constant at a first width w1.

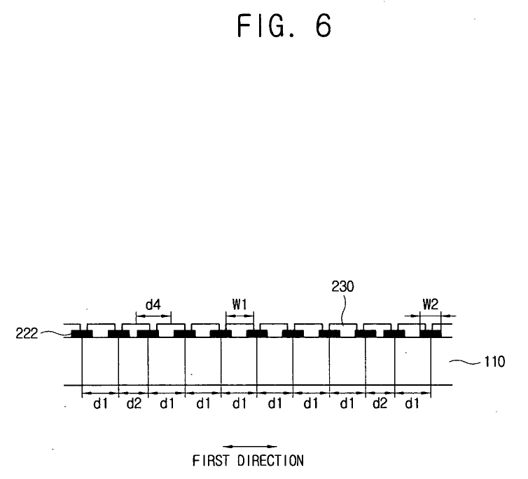

FIG. 6 is a sectional view illustrating alignment of the black matrixes with the color filters in the display device according to the first embodiment of the present invention.

As shown in FIG. 6, in the middle portion of the figure, the color filters 230 are formed at both sides around the centers of the vertical extending portions 222. However, in a portion far from the middle portion of the figure, the color filters 230 are formed at both sides around portions far from the centers of the vertical extending portions 222. In other words, further from the middle portion of the figure, there is higher possibility of misalignment of the black matrixes 220 with the color filters 230.

This is because the black matrixes 220 are formed on the second insulating substrate 210 made of plastic. Since plastics have a thermal expansion coefficient higher than glass, a plastic insulating substrate is apt to expand when heated, unlike a glass insulating substrate.

Plastic insulating substrate 210 expands by the heat generated during various processes, such as coating, exposure, development, baking and so on, which are repeatedly performed in manufacturing color filters 230. The expansion of the plastic insulating substrate 210 causes expansion of the black matrixes 220 formed on the plastic insulating substrate 110, which may result in misalignment of the black matrixes 220 with the color filters 230. Excessive expansion of the black matrixes 220 may cause the color filters 230 not to be located at the openings C of the black matrixes 220, which may result in leakage of light.

For example, if the diagonal of plastic insulating substrate is 7 inches, the amount of expansion of the plastic insulating substrate may be in an order of about 50 μm. Expansion in a long side direction of the second substrate 200 is larger than that in a short side direction of the second substrate 200, and thus increasing an interval between the vertical extending portions 222.

In this embodiment, the interval between the vertical extending portions 222 includes the relatively small second interval d2, as mentioned above. Expansion of the interval between the vertical extending portions 222, that is, expansion of the black matrixes 220 in the first direction, is restricted by the second interval d2, thus decreasing the misalignment of the black matrixes 220 with the color filters 230. Since the second interval d2 is formed with a constant pattern throughout the second substrate 200, the misalignment of the black matrixes 220 with the color filters 230 decreases throughout the second substrate 200.

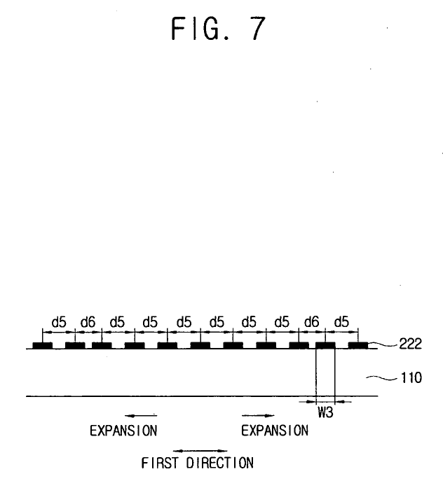

FIG. 7 is a sectional view used to explain a manufacturing method of the display device according to the first embodiment of the present invention, showing a state where the black matrixes 220 are formed on the second insulating substrate 210.

As shown in FIG. 7, the interval between the vertical extending portions 222 includes a fifth interval d5 and a sixth interval d6 smaller than the fifth interval d5. The fifth interval d5 and the sixth interval d6 have a constant pattern of one sixth interval d6 every six fifth intervals d5.

While the color filters 230 are formed, the black matrixes 220 are expanded into the state shown in FIG. 6. According to the expansion, the fifth interval d5 increases to the first interval d1 and the sixth interval d6 increases to the second interval d2. In addition, the width of the vertical extending portions 222 increases from a third width w3 to a second width w2.

After forming the black matrixes 220, the second substrate 200 is completed when the color filter layer 230, the overcoat layer 241 and the common electrode 251 are formed on the black matrixes 220.

The first substrate 100 may be manufactured according to a known method, and therefore, explanation thereof will be omitted for the sake of brevity. Bonding of the first substrate 100 to the second substrate 200 and injection of the liquid crystal layer 400 may also be performed according to a known method, and therefore, explanation thereof will be omitted for the sake of brevity.

The above-described first embodiment may be modified in various ways. For example, the interval between the vertical extending portions 222 may have an irregular pattern and may include 3 or more different intervals.

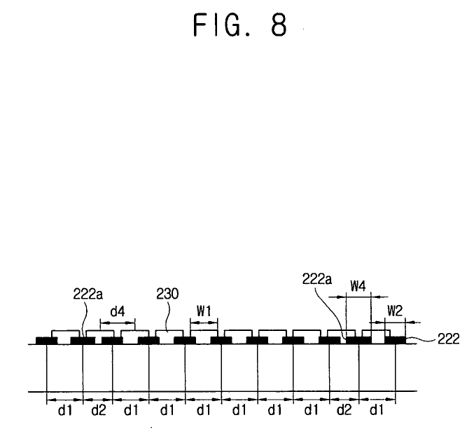

FIG. 8 is a sectional view illustrating alignment of black matrixes with color filters in a display device according to a second embodiment of the present invention.

Vertical extending portions 222 include an enlarged vertical extending portions 222a having a width larger than the second width w2 of adjacent vertical extending portions 222. The interval between the enlarged vertical extending portions 222a and the adjacent vertical extending portions 222 is the second interval d2.

A fourth width w4 as a width of the enlarged vertical extending portions 222a may be 102% to 130% of the second width w2. The size of the fourth width w4 depends on the thermal expansion coefficient of the second insulating substrate 210, temperature conditions for manufacture of the color filters 230, etc.

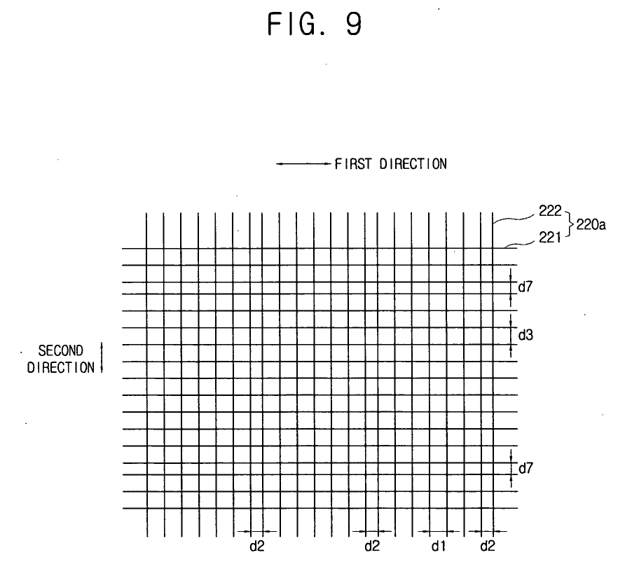

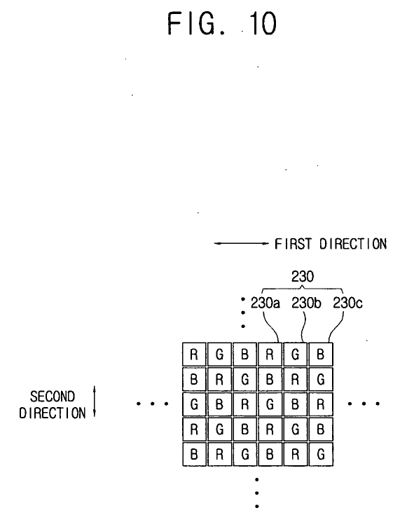

Hereinafter, a display device according to a third embodiment of the present invention will be described with reference to FIGS. 9 and 10.

The interval between vertical extending portions 222 includes a first interval d1 and a second interval d2 smaller than the first interval d2, as in the first embodiment. The first interval d1 and the second interval d2 have a regular pattern of one second interval d2 every six first intervals d1.

In the third embodiment, in addition, the interval between horizontal extending portions 221 includes a third interval d3 and a seventh interval d7 smaller than the third interval d2. The third interval d3 and the seventh interval d7 have a constant pattern of one seventh interval d7 every 10 third intervals d3. The reason for irregularity of the interval between the horizontal extending portions 221 is that the third embodiment is different in arrangement of the color filters 230 from the first embodiment.

Referring to FIG. 10, the color filters 230 include sub layers 230a, 230b and 230c repeated in the first direction. Further, adjacent sub layers 230a, 230b and 230c in the second direction different from each other. Accordingly, unlike the first embodiment, there may occur misalignment of the black matrixes 220 with the color filters 230 in the second direction. The seventh interval d7 formed in the horizontal extending portions 221 serves to decrease the misalignment.

The seventh interval d7 may be 70% to 98% of the third interval d3. If the seventh interval d7 is less than 70% of the third interval d3, an area of the opening C is excessively reduced. If the seventh interval d7 is more than 98% of the third interval d3, an alignment between color filters 230 and black matrixes 220 deteriorates. A size of the seventh interval d7 depends on a thermal expansion coefficient of the second insulating substrate 210, temperature conditions for manufacture of the color filters 230, a ratio of the third interval d3 to the seventh interval d7, etc.

As an alternative, the interval between the horizontal extending portions 221 may have an irregular pattern and may include three or more different intervals.

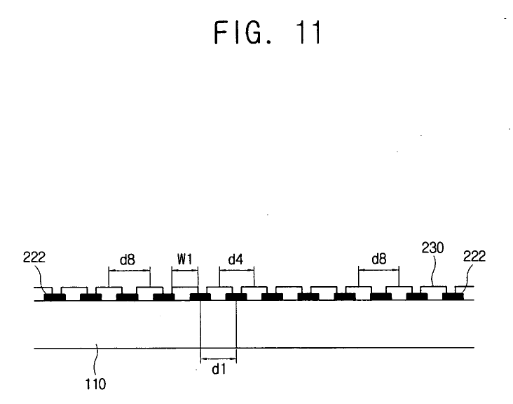

Hereinafter, a display device according to a fourth embodiment of the present invention will be described with reference to FIG. 11.

As shown in FIG. 11, vertical extending portions 222 are uniformly arranged with a first interval d1. The width of color filters 230 is constant with a first width w1, but the interval of the color filters 230 includes a fourth interval d4 and an eighth interval d8 larger than the fourth interval d4. The fourth interval d4 and the eighth interval d8 have a constant pattern of one eighth interval d8 every six fourth intervals d4. The eighth interval d8 widens the interval between the color filters 230 in response to expansion of the second insulating substrate 210 and the black matrixes 220, and thus decreasing misalignment of the black matrixes 220 with the color filters 230.

As an alternative, it may be configured that the interval between the black matrixes 220 and the interval between the color filters 230 are made irregular simultaneously. For example, the black matrixes 220 may have a narrow interval every a specified position, while the color filters 230 may have a wide interval every a specified position.

As apparent from the above description, the present invention provides a display device having reduced misalignment of black matrixes with color filters even when a plastic insulating substrate is used.

In addition, the present invention provides a manufacturing method of a display device having improved alignment of black matrixes with color filters even when a plastic insulating substrate is used.

Although a few embodiments of the present invention have been shown and described, it will be appreciated by those skilled in the art that changes may be made in these embodiments without, however, departing from the spirit and scope of the invention.

What is claimed is:

1. A display device comprising:
a first insulating substrate comprising a first insulating substrate and thin film transistors formed on the first insulating substrate,
a second substrate facing the first substrate and comprising a second insulating substrate made of plastic and a black matrix formed on the first insulating substrate, the black matrix comprising a plurality of horizontal extending portions extending in a first direction and a plurality of vertical extending portions extending in a second direction perpendicular to the first direction and disposed at an irregular interval; and
a liquid crystal layer located between the first substrate and the second substrate.

2. The display device according to claim 1, wherein an interval between adjacent vertical extending portions includes first vertical intervals and second vertical intervals smaller than the first vertical intervals, and
wherein the second vertical intervals are formed with a specified number of vertical extending portions interposed therebetween.

3. The display device according to claim 1, wherein an interval between adjacent vertical extending portions includes first vertical intervals and second vertical intervals smaller than the first vertical intervals, and wherein the vertical extending portions comprise:
a first sub vertical portion having a first vertical width; and
a second sub vertical portion having a second vertical width larger than the first vertical width.

4. The display device according to claim 3, wherein at least one of a pair of vertical extending portions with the second vertical interval therebetween is the second sub vertical portion.

5. The display device according to claim 1, wherein the second insulating substrate has a rectangular shape, and
wherein the second direction is parallel to short sides of the second insulating substrate.

6. The display device according to claim 5, wherein the second substrate further comprises color filters formed on the black matrixes with a constant interval.

7. The display device according to claim 5, wherein an interval between the adjacent horizontal extending portions is constant.

8. The display device according to claim 5, wherein an interval between the adjacent horizontal extending portions includes first horizontal intervals and second horizontal intervals smaller than the first horizontal intervals, and
wherein the second horizontal intervals are formed with specified number of the horizontal extending portions interposed therebetween.

9. The display device according to claim 5, wherein an interval between the adjacent horizontal extending portions includes first horizontal intervals and second horizontal intervals smaller than the first horizontal intervals, and
wherein the horizontal extending portions comprise:
a first sub horizontal portion having a first horizontal width; and
a second sub horizontal portion having a second horizontal width larger than the first horizontal width.

10. The display device according to claim 9, wherein at least one of a pair of horizontal extending portions with the second horizontal interval therebetween is the second sub horizontal portion.

11. The display device according to claim 1, further comprising color filters formed on the black matrixes and the second insulating substrate, the color filters having a plurality of sub layers extending in the second direction and having an irregular interval.

12. The display device according to claim 11, wherein the width of the sub layers is constant.

13. A manufacturing method of a display device, comprising:
forming a black matrix on an insulating substrate made of plastic, the black matrix comprising a plurality of horizontal extending portions extending in a first direction and a plurality of vertical extending portions having an irregular interval and extending in a second direction perpendicular to the first direction; and
forming color filters in openings formed in the black matrix with a constant interval.

14. The manufacturing method according to claim 13, wherein an interval between the adjacent vertical extending portions includes first vertical intervals and second vertical intervals smaller than the first vertical intervals, and
wherein the second vertical intervals are formed with the specified number of the vertical extending portions interposed therebetween.

15. The manufacturing method according to claim 13, wherein an interval between the adjacent vertical extending portions includes first vertical intervals and second vertical intervals smaller than the first vertical intervals, and
wherein the vertical extending portions comprise:
a first sub vertical portion having a first vertical width; and
a second sub vertical portion having a second vertical width larger than the first vertical width.

16. The manufacturing method according to claim 15, wherein at least one of a pair of vertical extending portions with the second vertical interval therebetween is the second sub vertical portion.

17. The manufacturing method according to claim 13, wherein the second insulating substrate has a rectangular shape, and
wherein the second direction is parallel to short sides of the second insulating substrate.
